(19) United States
(12) Patent Application Publication
(10) Pub. No.: US 2026/0234882 A1
(43) Pub. Date: Aug. 13, 2026

(54) Cleaning System

(71) Applicant: Daifuku Co., Ltd., Osaka-shi (JP)

(72) Inventors: Takeshi Abe, Hinocho (JP); Yasuyuki Okumura, Hinocho (JP)

(21) Appl. No.: 19/530,871

(22) Filed: Feb. 5, 2026

(30) Foreign Application Priority Data
Feb. 7, 2025 (JP) 2025-019095

(51) Int. Cl. E01H 8/10; B61B 3/02; H10P 72/30

(52) U.S. Cl. CPC E01H 8/10; B61B 3/02; H10P 72/3216; H10P 72/3221

(57) ABSTRACT

A cleaning system includes a travel rail that forms a transport path for an article transport vehicle, and a cleaning vehicle that can travel on the travel rail. The cleaning vehicle includes a right suction port, a left suction port, a negative pressure generation unit that is shared by the right suction port and the left suction port and generates negative pressure, a right flow path, a left flow path, and a communication state changing device. The communication state changing device is configured to be able to switch between a both-sides communication state in which both the right and left flow paths are in communication, a right-side communication state in which the right flow path is in communication and the left flow path is blocked, and a left-side communication state in which the left flow path is in communication and the right flow path is blocked.

### CROSS-REFERENCE TO RELATED APPLICATION

This application claims priority to Japanese Patent Application No. 2025-019095 filed February 7, 2025, the disclosure of which is hereby incorporated by reference in its entirety.

### BACKGROUND OF THE INVENTION

### Field of the Invention

The present invention relates to a cleaning system including a travel rail that forms a transport path for an article transport vehicle, and a cleaning vehicle that can travel on the travel rail.

### Description of Related Art

For example, Japanese Patent Laid-Open Publication No. 2000-271552 (JP 2000-271552) discloses a technology for cleaning a transport path of an article transport vehicle. In the following description of the background art, reference numerals in parentheses refer to those in JP 2000-271552.

JP 2000-271552 discloses a travel path (1) disposed on a ceiling and a transport vehicle (2) that travels on the travel path (1). The transport vehicle (2) receives a supply of power in a contactless manner from a power supply line (5) installed along the travel path (1) and travels on the travel path (1), transporting cassettes storing semiconductor wafers and the like to a destination.

In the technology disclosed in JP 2000-2715521, two dust suction nozzles (28, 29) are connected to a common vacuum cleaner (10), and the two dust suction nozzles (28, 29) simultaneously suck up dust. For this reason, the suction force generated by the vacuum cleaner (10) is distributed to the two dust suction nozzles (28, 29), and the suction force of each dust suction nozzle is reduced. Although there is an advantage that the plurality of dust suction nozzles (28, 29) can clean a plurality of locations simultaneously, there is a disadvantage that, for example, locations with a large amount of dust accumulation cannot be cleaned sufficiently in some cases since the suction power is reduced.

### SUMMARY OF THE INVENTION

In view of the above circumstances, there is desire for a cleaning system that can efficiently clean a transport path of an article transport vehicle.

The technology for solving the above-described problems is as follows.

A cleaning system including:

a travel rail forming a transport path for an article transport vehicle; and

a cleaning vehicle capable of traveling on the travel rail,

in which the travel rail includes a right rail on which a right wheel of the article transport vehicle rolls and a left rail on which a left wheel of the article transport vehicle rolls,

the cleaning vehicle includes:

a right suction port disposed to oppose a rolling surface of the right rail;

a left suction port disposed to oppose a rolling surface of the left rail;

a negative pressure generation unit that is shared by the right suction port and the left suction port, and is configured to generate negative pressure;

a right flow path connecting the right suction port and the negative pressure generation unit;

a left flow path connecting the left suction port and the negative pressure generation unit; and

a communication state changing device configured to change a communication state of each of the right flow path and the left flow path, and

the communication state changing device is configured to be able to switch between

a both-sides communication state in which both the right flow path and the left flow path are in communication,

a right-side communication state in which the right flow path is in communication and the left flow path is blocked, and

a left-side communication state in which the left flow path is in communication and the right flow path is blocked.

According to this configuration, by setting the communication state of the flow path to the both-sides communication state, suction can be performed by both the right suction port and the left suction port, and both the right rail and the left rail can be cleaned simultaneously. In addition, by setting the communication state of the flow path to the right-side communication state, suction can be performed from the right suction port without suction from the left suction port. For this reason, the right rail can be cleaned with the suction force of the right suction port being higher than that in the both-sides communication state. Similarly, by setting the communication state of the flow path to the left-side communication state, suction can be performed from the left suction port without suction from the right suction port. For this reason, the left rail can be cleaned with the suction force of the left suction port being higher than that in the both-sides communication state. In this way, with this configuration, the rail to be cleaned can be selected as needed, and the cleaning capability for each rail can be changed, making it easier to improve the efficiency of cleaning the transport path.

Further features and advantages of the technology according to the present disclosure will become more apparent from the following description of exemplary and non-limiting embodiments, which will proceed with reference to the drawings.

### BRIEF DESCRIPTION OF THE DRAWINGS

FIG. 1 is a plan view of an article transport facility including a cleaning system.

FIG. 2 is a diagram showing travel on both wheels of an article transport vehicle.

FIG. 3 is a diagram showing travel on one wheel of the article transport vehicle.

FIG. 4 is a diagram showing a main structure of a cleaning vehicle.

FIG. 5 is a diagram showing communication states of flow paths.

FIG. 6 is a diagram showing a structure of a cleaning vehicle according to another embodiment.

FIG. 7 is a diagram showing a cleaning system according to another embodiment.

### DESCRIPTION OF THE INVENTION

A cleaning system constitutes part or all of an article transport facility and cleans a transport path of an article transport vehicle. Hereinafter, an embodiment of the cleaning system will be described, taking a case where the cleaning system is applied to an article transport facility as an example.

First, an article transport facility to which the cleaning system according to this embodiment is applied will be described.

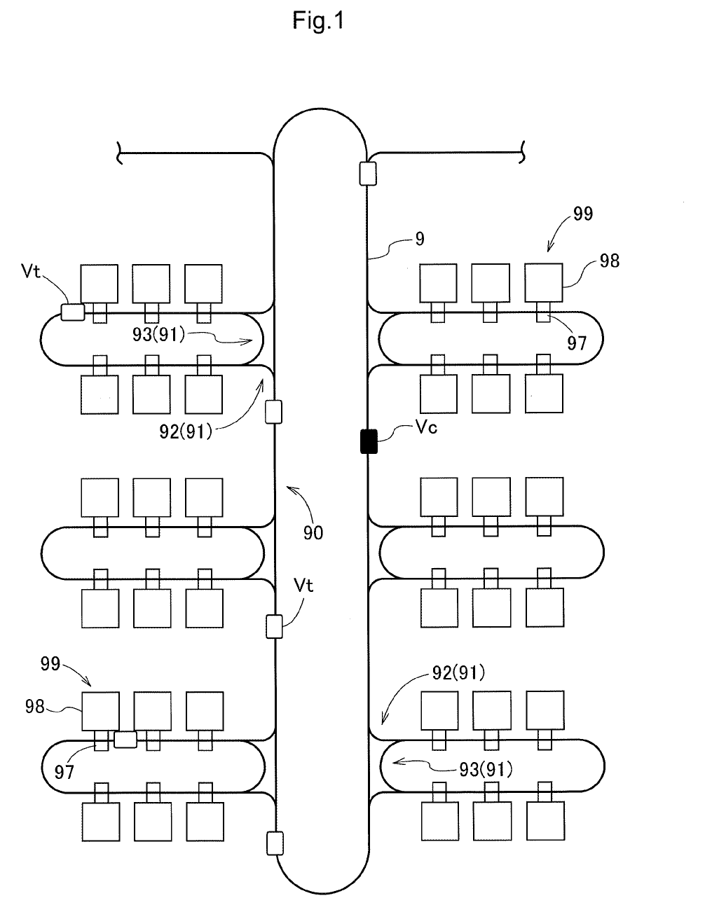

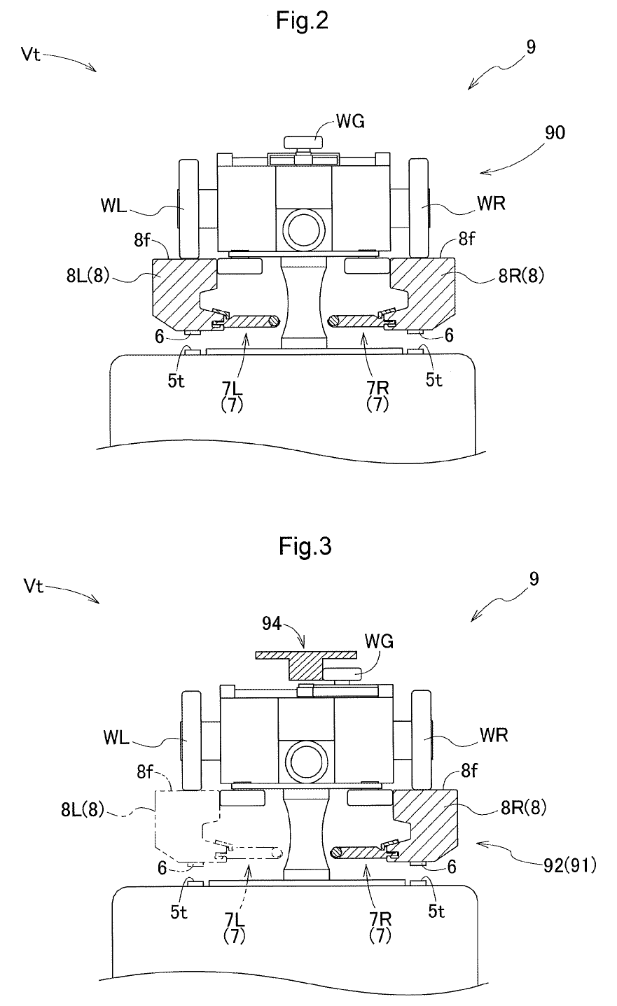

As shown in FIG. 1, the article transport facility includes an article transport vehicle Vt that transports an article, a travel rail 8 (see also FIG. 2) that is installed near a ceiling of the facility and forms a transport path 9 for the article transport vehicle Vt, and transfer target locations 99 where articles are transferred to and from the article transport vehicle Vt. That is, in this example, the article transport facility is configured as a ceiling transport facility that transports articles near a ceiling.

As shown in FIG. 2, the transport path 9 is constituted using a pair of travel rails 8. A power supply unit 7 is provided on the transport path 9. The article transport vehicle Vt is configured to receive a supply of power in a contactless manner from the power supply unit 7 to ensure at least a portion of its motive power source.

As shown in FIG. 1, the transport path 9 includes straight paths 90 and curved paths 91. The curved paths 91 are provided at least in a branching section where the path branches off and in a merging section where a plurality of paths merge.

The transfer target location 99 is provided with a processing device 98 that processes the article, and a support platform 97 that is arranged adjacent to the processing device 98 and holds the article. In this embodiment, the article transport vehicle Vt transports an article that has not yet been processed by the processing device 98 to the support platform 97, and transports an article that has been processed by the processing device 98 from the support platform 97 to a designated transport destination. For example, the article is a container that stores a processing target to be processed by the processing device 98, and the above-mentioned “processing of the article” means processing of the processing target stored in the article. The article may be a wafer storage container (a so-called FOUP: Front Opening Unified Pod) that stores a wafer, or a reticle storage container (a so-called reticle pod) that stores a reticle. If the article is an FOUP, the processing target is a wafer. If the article is a reticle pod, the processing target is a reticle.

As shown in FIG. 2, the travel rail 8 includes a right rail 8R on which a right wheel WR of the article transport vehicle Vt rolls, and a left rail 8L on which a left wheel WL of the article transport vehicle Vt rolls.

In this embodiment, the power supply unit 7 includes a right power supply unit 7R arranged along the right rail 8R and a left power supply unit 7L arranged along the left rail 8L. Each of the right power supply unit 7R and the left power supply unit 7L includes a motive power line. Both the right power supply unit 7R and the left power supply unit 7L supply power to the article transport vehicle Vt in a contactless manner, and the article transport vehicle Vt is configured to be able to travel along the transport path 9 using the power obtained thereby.

In this embodiment, a plurality of position information holding units 6 are provided along the transport path 9. Each position information holding unit 6 holds position information corresponding to its own location. In other words, each position information holding unit 6 holds address information for a corresponding point on the transport path 9.

The article transport vehicle Vt includes a position information acquisition unit 5t that acquires information about its own current position. In this embodiment, the article transport vehicle Vt can ascertain its own current position by acquiring the position information stored in the position information holding unit 6 using the position information acquisition unit 5t. For example, the position information holding unit 6 is configured using a one-dimensional code, a two-dimensional code, an IC tag, or the like. The position information acquisition unit 5t is configured using a means such as a reader that can acquire information from such information storage media.

As shown in FIG. 2, both the right rail 8R and the left rail 8L are present on the straight path 90. The article transport vehicle Vt travels on both wheels on the straight path 90, with the right wheel WR in contact with the right rail 8R and the left wheel WL in contact with the left rail 8L.

As shown in FIG. 3, only one of the right rail 8R and the left rail 8L can be present on the curved path 91. For example, only one of the right rail 8R and the left rail 8L is present on the curved path 91 provided in the branching section or merging section described above. However, as with the straight path 90, there may also be a curved path 91 where both the right rail 8R and the left rail 8L are present.

The curved path 91 includes a right curved path 92 that curves to the right using the travel direction of the article transport vehicle Vt as a reference, and a left curved path 93 that curves to the left using the travel direction as a reference. FIG. 3 shows the right curved path 92. Only the right rail 8R out of the right rail 8R and the left rail 8L is present on the right curved path 92. Although not shown in the drawing, the left curved path 93 has a symmetrical structure to the right curved path 92. Only the left rail 8L out of the right rail 8R and the left rail 8L is present on the left curved path 93.

In this embodiment, the article transport vehicle Vt travels on one wheel on the curved path 91, with only the right wheel WR in contact with the right rail 8R or only the left wheel WL in contact with the left rail 8L. As shown in FIG. 3, the article transport vehicle Vt travels on one wheel on the right curved path 92, with only the right wheel WR in contact with the right rail 8R. Although not shown in the drawings, the article transport vehicle Vt travels on one wheel on the left curved path 93, with only the left wheel WL in contact with the left rail 8L.

When the article transport vehicle Vt travels on one wheel on the right curved path 92, it is supported by two main points, namely the right wheel WR in contact with the right rail 8R and a guide wheel WG in contact with a guide rail 94 from the right side. When the article transport vehicle Vt travels on one wheel on the left curved path 93, it is supported by two main points, namely the right wheel WR in contact with the left rail 8L, and the guide wheel WG in contact with the guide rail 94 from the left side.

The guide wheel WG is used to allow the article transport vehicle Vt to proceed in any direction in a branch section. The guide wheel WG moves left and right to change its position. When the article transport vehicle Vt is to proceed to the right in a branch section, the guide wheel WG moves to the right, comes into contact with the guide rail 94 from the right side, and is guided by the guide rail 94. When the article transport vehicle Vt is to proceed to the left in a branch section, the guide wheel WG moves to the left, comes into contact with the guide rail 94 from the left side, and is guided by the guide rail 94.

On the curved path 91 where the article transport vehicle Vt travels on one wheel, only one of the right wheel WR and the left wheel WL comes into contact with the travel rail 8, and therefore the contact load on the travel rail 8 is concentrated on only one wheel, making the travel wheel more susceptible to wear. For this reason, on the curved path 91, dust generated by the travel wheel is more likely to accumulate than on the straight path 90.

The cleaning system according to this embodiment is provided as part of such an article transport facility. The cleaning system is a system for cleaning the transport path 9 of the article transport vehicle Vt, and includes a travel rail 8 that forms the transport path 9 of the article transport vehicle Vt, a cleaning vehicle Vc that can travel on the travel rail 8, and a power supply unit 7 that is provided along the transport path 9 and supplies power to the article transport vehicle Vt on the transport path 9.

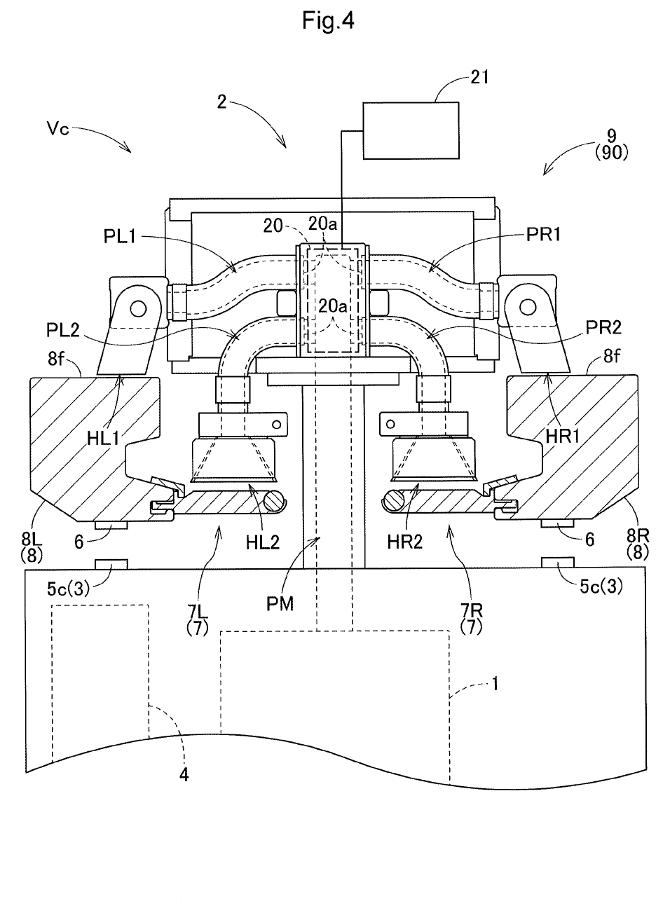

As shown in FIG. 4, the cleaning vehicle Vc is configured to clean the travel rail 8. The cleaning vehicle Vc cleans the travel rail 8 while traveling on the travel rail 8. The structure for the cleaning vehicle Vc to travel on the travel rail 8 may be the same as the structure for the article transport vehicle Vt to travel on the travel rail 8. Accordingly, the cleaning vehicle Vc has at least a right wheel (not shown) that rolls on the right rail 8R and a left wheel (not shown) that rolls on the left rail 8L.

The cleaning vehicle Vc includes a first right suction port HR1 (corresponding to the “right suction port”) disposed to oppose a rolling surface 8f of the right rail 8R, a first left suction port HL1 (corresponding to the “left suction port”) disposed to oppose the rolling surface 8f of the left rail 8L, a negative pressure generation unit 1 that is shared by the first right suction port HR1 and the first left suction port HL1 and generates negative pressure, a first right flow path PR1 (corresponding to the “right flow path”) connecting the first right suction port HR1 and the negative pressure generation unit 1, a first left flow path PL1 (corresponding to the “left flow path”) connecting the first left suction port HL1 and the negative pressure generation unit 1, and a communication state changing device 2 that changes the communication state of each of the first right flow path PR1 and the first left flow path PL1.

In this embodiment, the cleaning vehicle Vc includes a second right suction port HR2 disposed to oppose the right power supply unit 7R, a second left suction port HL2 disposed to oppose the left power supply unit 7L, a second right flow path PR2 connecting the second right suction port HR2 and the negative pressure generation unit 1, and a second left flow path PL2 connecting the second left suction port HL2 and the negative pressure generation unit 1.

The negative pressure generation unit 1 is accommodated in the main body of the cleaning vehicle Vc, which is disposed below the travel rail 8. The negative pressure generation unit 1 includes, for example, a fan. The negative pressure generation unit 1 generates negative pressure and applies a suction force to each suction port by driving the fan.

The cleaning vehicle Vc has a main flow path PM that extends upward from the negative pressure generation unit 1. The first right flow path PR1 and the first left flow path PL1 branch off to the left and right from the main flow path PM. The second right flow path PR2 and the second left flow path PL2 branch off to the left and right from the main flow path PM.

The first right flow path PR1 extends from the main flow path PM toward the right rail 8R, and is provided with the first right suction port HR1 at its leading end.

The first left flow path PL1 extends from the main flow path PM toward the left rail 8L, and is provided with the first left suction port HL1 at its leading end.

The second right flow path PR2 extends from the main flow path PM toward the right power supply unit 7R, and is provided with the second right suction port HR2 at its leading end.

The second left flow path PL2 extends from the main flow path PM toward the left power supply unit 7L, and is provided with the second left suction port HL2 at its leading end.

Although not shown in the drawings, it is also preferable that each suction port is provided with a brush for removing dust accumulated at the cleaning target location.

In this embodiment, the communication state changing device 2 includes a valve 20 that opens and closes each flow path other than the main flow path PM (first right flow path PR1, first left flow path PL1, second right flow path PR2, second left flow path PL2), and a drive source 21 that drives the valve 20.

In this embodiment, the valve 20 is configured using a cylindrical member that is arranged along the inner peripheral surface of the main flow path PM. The valve 20 is driven by the drive source 21 and is configured to rotate around the axis of the cylindrical member. The drive source 21 includes a motor for rotating the valve 20.

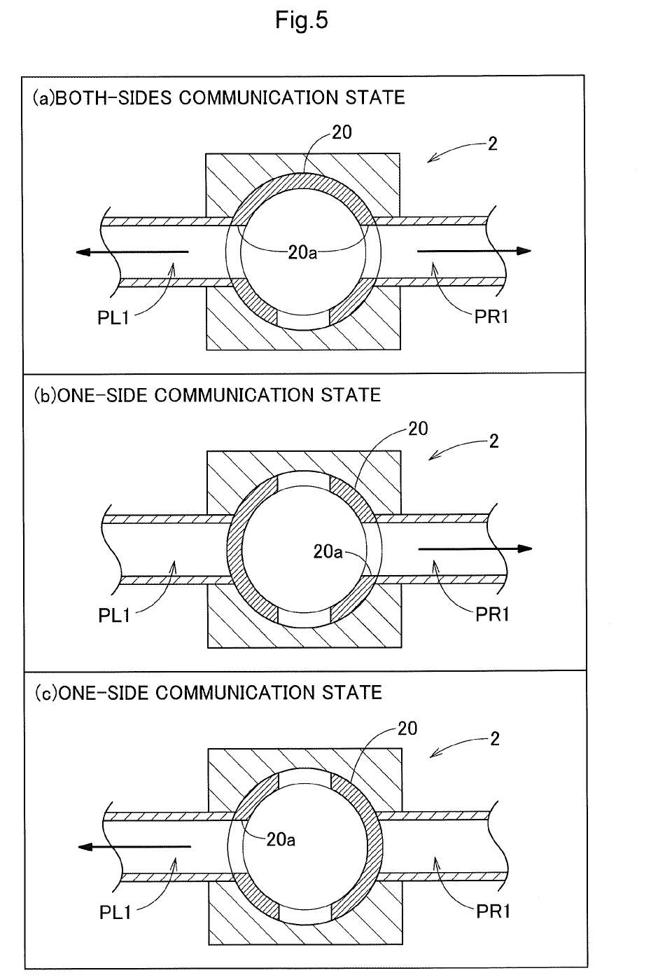

In this embodiment, the valve 20 has a plurality of openings 20a (see also FIG. 5). The openings 20a are provided at a height corresponding to the base end portions (end portions opposite to the suction ports, which are the leading end portions) of the first right flow path PR1, the first left flow path PL1, the second right flow path PR2, and the second left flow path PL2. At each height, a plurality of the openings 20a are provided intermittently along the peripheral direction of the cylindrical valve 20 (see FIG. 5).

When the valve 20 rotates to overlap with the openings 20a of the valve 20, each flow path is brought into communication with the main flow path PM. On the other hand, when each flow path does not overlap with the openings 20a of the valve 20, the valve 20 acts as a wall and blocks the flow path from the main flow path PM.

The communication state changing device 2 is configured to be able to switch between a single-path communication state in which only one of the first right flow path PR1, the first left flow path PL1, the second right flow path PR2, and the second left flow path PL2 is in communication, and a multiple-path communication state in which two or more of the flow paths are in communication.

In this embodiment, the negative pressure generation unit 1 is configured to generate a constant negative pressure during its operation. In other words, the negative pressure generation unit 1 does not adjust the negative pressure during its operation. In this embodiment, the communication state changing device 2 switches the communication states of the flow paths, thereby adjusting the negative pressure at each suction port. In other words, when the communication state changing device 2 realizes the single-path communication state, there is only one flow path that is in communication with the negative pressure generation unit 1, and therefore the constant negative pressure generated by the negative pressure generation unit 1 is concentrated in only that one flow path, and the suction force in that flow path increases. On the other hand, when the communication state changing device 2 realizes the multiple-path communication state, there are a plurality of flow paths that are in communication with the negative pressure generation unit 1, and therefore the constant negative pressure generated by the negative pressure generation unit 1 is distributed to the plurality of flow paths, and the suction force in each flow path decreases.

In this manner, in this embodiment, the adjustment of the suction force is realized by the operation of the communication state changing device 2. In this example, the suction force of each suction port can be adjusted simply by rotating the cylindrical valve 20. Accordingly, it is possible to eliminate the need for complicated control.

In this embodiment, the cleaning system includes a control system 4 that controls each part of the cleaning vehicle Vc. The control system 4 is configured to execute tasks using hardware including an input device, an output device, a storage device, and a CPU, and software such as a program.

The control system 4 may be mounted on the cleaning vehicle Vc, or may be provided separately from the cleaning vehicle Vc and remotely control the cleaning vehicle Vc. Alternatively, the control system 4 may be configured by a combination of these.

In this embodiment, the control system 4 is configured to control the communication state changing device 2 to switch the communication state of each flow path.

In this embodiment, the cleaning vehicle Vc includes a path detection device 3 that detects whether the transport path 9 is the straight path 90 or the curved path 91. The control system 4 controls the communication state changing device 2 based on the detection result by the path detection device 3.

In this embodiment, the path detection device 3 detects the type of the transport path 9 as follows. That is, as described above, the basic structure for the cleaning vehicle Vc to travel along the transport path 9 is the same as that of the article transport vehicle Vt, and the cleaning vehicle Vc is configured to obtain position information (its own current position) from the position information holding units 6. In this example, the cleaning vehicle Vc acquires position information from the position information holding units 6 by a position information acquisition unit 5c in the same manner as the article transport vehicle Vt. The path detection device 3 is also configured to detect that the cleaning vehicle Vc is entering the curved path 91 in response to position information being acquired from the position information holding unit 6 provided upstream of the curved path 91. In this example, the position information acquisition unit 5c also functions as the path detection device 3.

In this manner, in this embodiment, the path detection device 3 can detect that the curved path 91 is present ahead of the cleaning vehicle Vc before the cleaning vehicle Vc enters the curved path 91. Based on the detection result, the control system 4 controls the communication state changing device 2 in advance such that the communication state of each flow path becomes a state suitable for cleaning the curved path 91. As described above, dust is more likely to accumulate on the curved path 91 than on the straight path 90. In addition, in the curved path 91 where only one of the right rail 8R and the left rail 8L is present, cleaning of the rail that is not present is not necessary, and therefore it is preferable to concentrate the suction force on the rail that is present. Therefore, in response to the path detection device 3 detecting the curved path 91, the control system 4 blocks unnecessary flow paths and allows only necessary flow paths to be in communication with the negative pressure generation unit 1.

As shown in FIG. 5, the communication state changing device 2 is configured to be able to switch the communication state of each flow path between a both-sides communication state and a one-side communication state. The one-side communication state includes a right-side communication state and a left-side communication state.

The both-sides communication state is a state in which both the first right flow path PR1 and the first left flow path PL1 are in communication with each other (see FIG. 5A). Although detailed illustration is omitted, in this example, a state in which both the second right flow path PR2 and the second left flow path PL2 are in communication with each other is also included in the both-sides communication state. Note that the both-sides communication state corresponds to the multiple-path communication state out of the above-mentioned single-path communication state and multiple-path communication state.

The right-side communication state is a state in which the first right flow path PR1 is in communication and the first left flow path PL1 is blocked (see FIG. 5B). Although detailed illustration is omitted, in this example, a state in which the second right flow path PR2 is in communication and the second left flow path PL2 is blocked is also included in the right-side communication state. Note that the state in which only the first right flow path PR1 is in communication and the state in which only the second right flow path PR2 is in communication correspond to the single-path communication state out of the above-mentioned single-path communication state and multiple-path communication state.

The left-side communication state is a state in which the first left flow path PL1 is in communication and the first right flow path PR1 is blocked (see FIG. 5C). Although detailed illustration is omitted, in this example, the left-side communication state also includes a state in which the second left flow path PL2 is in communication and the second right flow path PR2 is blocked. Note that the state in which only the first left flow path PL1 is in communication and the state in which only the second left flow path PL2 is in communication correspond to the single-path communication state out of the above-mentioned single-path communication state and multiple-path communication state.

In this embodiment, the control system 4 controls the communication state changing device 2 to automatically switch between the both-sides communication state, the right-side communication state, and the left-side communication state based on at least one of the current position of the cleaning vehicle Vc and the state of the travel rail 8. In this example, as described above, the control system 4 detects whether the path ahead of the cleaning vehicle Vc is the straight path 90 or the curved path 91 based on the current position of the cleaning vehicle Vc acquired from the position information holding unit 6, and controls the communication state of each flow path.

The control system 4 controls the communication state changing device 2 to switch the communication state of each flow path to the both-sides communication state (see FIG. 5A) in sections where the article transport vehicle Vt travels on both wheels (e.g., the straight paths 90), and to switch the communication state of each flow path to the right-side communication state (see FIG. 5B) or the left-side communication state (see FIG. 5C) in sections where the article transport vehicle Vt travels on one wheel (e.g., the curved paths 91).

As shown in FIG. 5, in this embodiment, the control system 4 is configured to control the communication state changing device 2 to change the phase of the cylindrical valve 20, thereby switching between the both-sides communication state and the one-side communication state (the right-side communication state or the left-side communication state).

In this embodiment, the plurality of openings 20a formed in the cylindrical valve 20 are arranged at only three positions, namely a 0° position, a 90° position, and a 180° position. In other words, no opening 20a is formed at a 270° position. This allows the openings 20a to overlap with both the first right flow path PR1 and the first left flow path PL1, which oppose each other at 180°, thereby realizing the both-sides communication state in which both the first right flow path PR1 and the first left flow path PL1 are in communication with the negative pressure generation unit 1. In addition, by changing the phase, the one-side communication state (the right-side communication state or the left-side communication state) can be achieved in which only one of the first right flow path PR1 and the first left flow path PL1 overlaps with the opening 20a and is in communication with the negative pressure generation unit 1. Note that although detailed illustration is omitted, various communication states for the second right flow path PR2 and the second left flow path PL2 can be realized in the same manner as above.

According to the cleaning system described above, the suction force at each suction port can be adjusted by opening and closing each flow path connected to the negative pressure generation unit 1, making it possible to efficiently clean the transport path 9 of the article transport vehicle Vt.

### Other Embodiments

Next, other embodiments will be described.

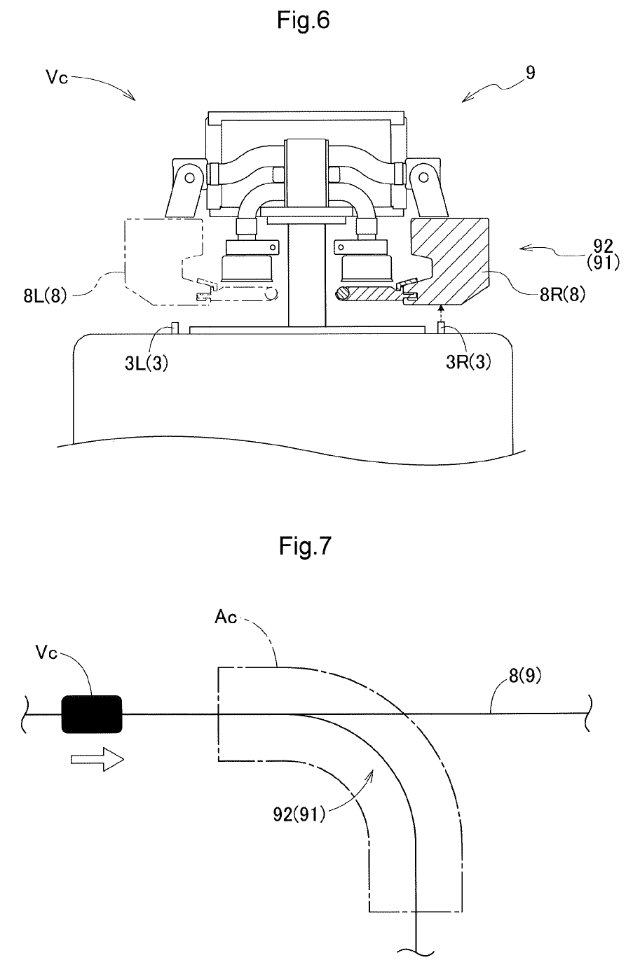

(1) In the above-described embodiment, an example was described in which, as a mode of distinguishing the type of the transport path 9, the path detection device 3 is configured to detect that the cleaning vehicle Vc is entering the curved path 91 in response to position information being acquired from the position information holding unit 6 provided upstream of the curved path 91. However, the present invention is not limited to such an example. For example, the type of the transport path 9 may also be distinguished using the configuration shown in FIG. 6. In the example shown in FIG. 6, the path detection device 3 includes a right rail detection unit 3R that is disposed at a position corresponding to the right rail 8R and detects the right rail 8R, and a left rail detection unit 3L that is disposed at a position corresponding to the left rail 8L and detects the left rail 8L. For example, the right rail detection unit 3R and the left rail detection unit 3L are configured using laser sensors, and detect a target object (rail) based on the optical axis being blocked. As shown in FIG. 6, the path detection device 3 detects that the transport path 9 is the right curved path 92 if the right rail detection unit 3R detects the right rail 8R and the left rail detection unit 3L does not detect the left rail 8L. Although detailed illustration is omitted, the path detection device 3 detects that the transport path 9 is the left curved path 93 if the left rail detection unit 3L detects the left rail 8L and the right rail detection unit 3R does not detect the right rail 8R.

(2) In the above embodiment, an example was described in which the control system 4 controls the communication state changing device 2 to automatically switch between the both-sides communication state, the right-side communication state, and the left-side communication state based on at least one of the current position of the cleaning vehicle Vc and the state of the travel rail 8. Regarding the “state of the travel rail 8”, the control system 4 may switch between the both-sides communication state, the right-side communication state, and the left-side communication state based on the “state of the travel rail 8”, for example, as follows. As shown in FIG. 7, the control system 4 is configured to determine whether or not an index (hereinafter referred to as a “contamination index”) representing the degree of contamination in a cleaning target section Ac of the travel rail 8 that is to be cleaned by the cleaning vehicle Vc is greater than or equal to a value set in advance. If the contamination index is less than the set value, the control system 4 performs cleaning on the cleaning target section Ac in the both-sides communication state. If the contamination index is less than the set value, the degree of contamination on the travel rail 8 is relatively low. With the above-described configuration, the suction force generated by the negative pressure generation unit 1 is dispersed to each flow path, but both the right rail 8R and the left rail 8L can be cleaned in a balanced manner. On the other hand, if the contamination index is greater than or equal to the set value, the control system 4 performs cleaning of the cleaning target section Ac a plurality of times, including at least one of cleaning in the right-side communication state and cleaning in the left-side communication state. If the contamination index is greater than or equal to the set value, the degree of contamination on the travel rail 8 is relatively high. With the above-described configuration, the suction force generated by the negative pressure generation unit 1 can be concentrated for cleaning locations that need cleaning. In addition, by cleaning the travel rail 8 a plurality of times, it becomes easier to remove the contamination from the travel rail 8 in a concentrated manner. Note that the “contamination index” can be calculated by estimating the amount of dust accumulated on the travel rail 8. For example, the amount of dust accumulated on the travel rail 8 may be estimated by capturing an image of the travel rail 8 using a camera sensor or the like mounted on the article transport vehicle Vt or the cleaning vehicle Vc and analyzing the captured image. Alternatively, this may be estimated by the frequency of cleaning. That is, it can be estimated that the longer the period that has elapsed since the most recent cleaning is, the greater the amount of dust that has accumulated on the travel rail 8 is, and the shorter the period is, the smaller the amount of dust is. Furthermore, the amount of dust accumulated on the travel rail 8 may be estimated based on the number of article transport vehicles Vt that have passed through the cleaning target section Ac within a predetermined period of time. It can be estimated that the greater the number of vehicles is, the greater the amount of accumulated dust is, and the smaller the number of vehicles is, the smaller the amount of accumulated dust is.

(3) In the above embodiment, an example was described in which the control system 4 is configured to control the communication state changing device 2 to switch the communication state of each flow path. However, the present invention is not limited to such an example. The communication state of each flow path may also be switched by manually operating the communication state changing device 2.

(4) In the above-described embodiment, an example was described in which the plurality of openings 20a formed in the cylindrical valve 20 are arranged at only three positions, namely the 0° position, the 90° position, and the 180° position. However, there is no limitation to such an example. The number of openings 20a provided in the valve 20 and the phase of their arrangement positions can be determined as appropriate. By adjusting the number and phase of the openings 20a, a single-path communication state and a multiple-path communication state can be suitably realized.

(5) In the above embodiment, the valve 20 is configured using a cylindrical member that is arranged along the inner peripheral surface of the main flow path PM and rotates about its axis. However, there is no limitation to such an example. The valve 20 may also be configured using, for example, a gate valve. The valve 20 may be configured to be able to realize the single-path communication state and the multiple-path communication state by using a gate valve provided in each of the four flow paths, or may be configured to be able to realize the single-path communication state and the multiple-path communication state by using a cylindrical rotary valve and a gate valve in combination.

(6) In the above embodiment, the communication states of the second right flow path PR2 and the second left flow path PL2 required for cleaning the power supply unit 7 were described. However, there is no limitation to such an example. For example, an article transport vehicle Vt equipped with a battery serving as a motive power source can travel in an area where no power supply unit 7 is provided. In such an area, there is no need to provide the power supply unit 7, and cleaning by the second right flow path PR2 and the second left flow path PL2 is not necessary. Accordingly, when the cleaning vehicle Vc travels in an area where no power supply unit 7 is provided, the communication state changing device 2 may set both the second right flow path PR2 and the second left flow path PL2 to a non-communication state.

(7) Note that the configurations disclosed in the above-described embodiments can be applied in combination with configurations disclosed in other embodiments, as long as no contradiction occurs. Regarding other configurations, the embodiments disclosed in this specification are merely examples in all respects. Accordingly, various modifications can be made as appropriate within the scope of the present disclosure.

### Summary of the Present Embodiment

The summary of the present embodiment will be described below.

A cleaning system including:

a travel rail forming a transport path for an article transport vehicle; and

a cleaning vehicle capable of traveling on the travel rail,

in which the travel rail includes a right rail on which a right wheel of the article transport vehicle rolls and a left rail on which a left wheel of the article transport vehicle rolls,

the cleaning vehicle includes:

a right suction port disposed to oppose a rolling surface of the right rail;

a left suction port disposed to oppose a rolling surface of the left rail;

a negative pressure generation unit that is shared by the right suction port and the left suction port, and is configured to generate negative pressure;

a right flow path connecting the right suction port and the negative pressure generation unit;

a left flow path connecting the left suction port and the negative pressure generation unit; and

a communication state changing device configured to change a communication state of each of the right flow path and the left flow path, and

the communication state changing device is configured to be able to switch between

a both-sides communication state in which both the right flow path and the left flow path are in communication,

a right-side communication state in which the right flow path is in communication and the left flow path is blocked, and

a left-side communication state in which the left flow path is in communication and the right flow path is blocked.

According to this configuration, by setting the communication state of the flow path to the both-sides communication state, suction can be performed by both the right suction port and the left suction port, and both the right rail and the left rail can be cleaned simultaneously. In addition, by setting the communication state of the flow path to the right-side communication state, suction can be performed from the right suction port without suction from the left suction port. For this reason, the right rail can be cleaned with the suction force of the right suction port being higher than that in the both-sides communication state. Similarly, by setting the communication state of the flow path to the left-side communication state, suction can be performed from the left suction port without suction from the right suction port. For this reason, the left rail can be cleaned with the suction force of the left suction port being higher than that in the both-sides communication state. In this way, with this configuration, the rail to be cleaned can be selected as needed, and the cleaning capability for each rail can be changed, making it easier to improve the efficiency of cleaning the transport path.

It is preferable that the cleaning system further includes a control system configured to control each part of the cleaning vehicle, and

the control system controls the communication state changing device to automatically switch between the both-sides communication state, the right-side communication state, and the left-side communication state based on at least one of a current position of the cleaning vehicle and a state of the travel rail.

According to this configuration, the control system can automatically determine whether cleaning is necessary for the right rail and the left rail, and execute cleaning based on that determination.

It is preferable that the transport path includes a straight path and a curved path, the article transport vehicle travels on both wheels on the straight path, with the right wheel in contact with the right rail and the left wheel in contact with the left rail,

the article transport vehicle travels on one wheel on the curved path, with only the right wheel in contact with the right rail or only the left wheel in contact with the left rail, and

the control system controls the communication state changing device to

switch the communication state to the both-sides communication state in a section where the article transport vehicle travels on both wheels, and

switch the communication state to the right-side communication state or the left-side communication state in a section where the article transport vehicle travels on one wheel.

Dust generated by wear of the wheels tends to accumulate on the transport path. For this reason, dust tends to accumulate on both the right and left rails in the section where the article transport vehicle travels on both wheels and dust tends to accumulate on either the right or left rail in the section where the article transport vehicle travels on one wheel. With this configuration, the need for cleaning of the right rail and the left rail can be determined based on whether the section in which the article transport vehicle is traveling is a section in which the article transport vehicle travels on both wheels or one wheel, and the communication state of the flow path can be appropriately switched.

It is preferable that the cleaning vehicle includes a path detection device configured to detect whether the transport path is the straight path or the curved path, and

the control system controls the communication state changing device based on the detection result by the path detection device.

According to this configuration, it is possible to realize a communication state of the flow path suitable for cleaning each of the straight path and the curved path based on the detection result by the path detection device.

It is preferable that the transport path includes a plurality of position information holding units provided along the transport path,

the position information holding units hold position information of the locations of the position information holding units,

the cleaning vehicle is configured to acquire the position information from the position information holding units, and

the path detection device detects that the cleaning vehicle is entering the curved path in response to the position information being acquired from the position information holding unit provided upstream of the curved path.

According to this configuration, a communication state of the flow path suitable for cleaning the curved path can be achieved before or at the timing when the cleaning vehicle enters the curved path.

It is preferable that the curved path includes a right curved path that curves to the right using the traveling direction of the article transport vehicle as a reference, and a left curved path that curves to the left using the traveling direction of the article transport vehicle as a reference,

only the right rail out of the right rail and the left rail is present on the right curved path,

only the left rail out of the right rail and the left rail is present on the left curved path,

the path detection device includes a right rail detection unit that is disposed at a position corresponding to the right rail and is configured to detect the right rail, and a left rail detection unit that is disposed at a position corresponding to the left rail and is configured to detect the left rail,

the path detection device detects that the transport path is the right curved path if the right rail detection unit detects the right rail and the left rail detection unit does not detect the left rail, and

the path detection device detects that the transport path is the left curved path if the left rail detection unit detects the left rail and the right rail detection unit does not detect the right rail.

According to this configuration, the path detection device can appropriately detect whether the transport path is a right curved path or a left curved path. Based on the detection result from the path detection device, a communication state of the flow path suitable for cleaning each of the right curved path and the left curved path can be realized.

It is preferable that a section of the travel rail that is to be cleaned by the cleaning vehicle is a cleaning target section, and the control system is configured to determine whether or not an index representing a degree of contamination in the cleaning target section is greater than or equal to a preset value,

the control system performs cleaning on the cleaning target section in the both-sides communication state if the index is less than the set value, and

the control system performs cleaning on the cleaning target section a plurality of times, including at least one of cleaning in the right-side communication state and cleaning in the left-side communication state if the index is greater than or equal to the set value.

According to this configuration, the communication state of the flow path can be appropriately switched depending on the degree of contamination in the cleaning target section, and cleaning can be performed an appropriate number of times, thereby making it possible to achieve more efficient operation.

It is preferable that the cleaning system further includes a power supply unit that is provided along the transport path and is configured to supply power to the article transport vehicle on the transport path,

the power supply unit includes a right power supply unit disposed along the right rail and a left power supply unit disposed along the left rail,

the cleaning vehicle includes:

a second right suction port disposed to oppose the right power supply unit;

a second left suction port disposed to oppose the left power supply unit;

a second right flow path connecting the second right suction port and the negative pressure generation unit; and

a second left flow path connecting the second left suction port and the negative pressure generation unit, and

the communication state changing device is configured to be able to switch between

a single-path communication state in which only one of the right flow path, the left flow path, the second right flow path, and the second left flow path is in communication, and

a multiple-path communication state in which two or more of the flow paths are in communication.

According to this configuration, in addition to the right rail and the left rail, the right power supply unit and the left power supply unit can also be candidates for locations to be cleaned. In addition, by switching between the single-path communication state and the multiple-path communication state, one or three or more candidates selected as appropriate from the above four candidates can be set as the cleaning target location.

### INDUSTRIAL APPLICABILITY

The technology disclosed herein can be used in a cleaning system that includes a travel rail that forms a transport path for an article transport vehicle, and a cleaning vehicle that can travel on the travel rail.

What is claimed is:

1. A cleaning system comprising:
a travel rail forming a transport path for an article transport vehicle; and
a cleaning vehicle capable of traveling on the travel rail, and
wherein:
the travel rail comprises a right rail on which a right wheel of the article transport vehicle rolls and a left rail on which a left wheel of the article transport vehicle rolls,
the cleaning vehicle comprises:
a right suction port disposed to oppose a rolling surface of the right rail;
a left suction port disposed to oppose a rolling surface of the left rail;
a negative pressure generation unit that is shared by the right suction port and the left suction port, and is configured to generate negative pressure;
a right flow path connecting the right suction port and the negative pressure generation unit;
a left flow path connecting the left suction port and the negative pressure generation unit; and
a communication state changing device configured to change a communication state of each of the right flow path and the left flow path, and
the communication state changing device is configured to be able to switch between
a both-sides communication state in which both the right flow path and the left flow path are in communication,
a right-side communication state in which the right flow path is in communication and the left flow path is blocked, and
a left-side communication state in which the left flow path is in communication and the right flow path is blocked.

2. The cleaning system according to claim 1, further comprising:
a control system configured to control each part of the cleaning vehicle, and
wherein the control system controls the communication state changing device to automatically switch between the both-sides communication state, the right-side communication state, and the left-side communication state based on at least one of a current position of the cleaning vehicle and a state of the travel rail.

3. The cleaning system according to claim 2, wherein:
the transport path comprises a straight path and a curved path,
the article transport vehicle travels on both wheels on the straight path, with the right wheel in contact with the right rail and the left wheel in contact with the left rail,
the article transport vehicle travels on one wheel on the curved path, with only the right wheel in contact with the right rail or only the left wheel in contact with the left rail, and
the control system controls the communication state changing device to
switch the communication state to the both-sides communication state in a section where the article transport vehicle travels on both wheels, and
switch the communication state to the right-side communication state or the left-side communication state in a section where the article transport vehicle travels on one wheel.

4. The cleaning system according to claim 3, wherein:
the cleaning vehicle comprises a path detection device configured to detect whether the transport path is the straight path or the curved path, and
the control system controls the communication state changing device based on the detection result by the path detection device.

5. The cleaning system according to claim 4, wherein:
the transport path comprises a plurality of position information holding units provided along the transport path,
the position information holding units hold position information of the locations of the position information holding units,
the cleaning vehicle is configured to acquire the position information from the position information holding units, and
the path detection device detects that the cleaning vehicle is entering the curved path in response to the position information being acquired from the position information holding unit provided upstream of the curved path.

6. The cleaning system according to claim 4, wherein:
the curved path comprises a right curved path that curves to the right using the traveling direction of the article transport vehicle as a reference, and a left curved path that curves to the left using the traveling direction of the article transport vehicle as a reference,
only the right rail out of the right rail and the left rail is present on the right curved path,
only the left rail out of the right rail and the left rail is present on the left curved path,
the path detection device comprises a right rail detection unit that is disposed at a position corresponding to the right rail and is configured to detect the right rail, and a left rail detection unit that is disposed at a position corresponding to the left rail and is configured to detect the left rail,
the path detection device detects that the transport path is the right curved path if the right rail detection unit detects the right rail and the left rail detection unit does not detect the left rail, and
the path detection device detects that the transport path is the left curved path if the left rail detection unit detects the left rail and the right rail detection unit does not detect the right rail.

7. The cleaning system according to claim 2, wherein:
a section of the travel rail that is to be cleaned by the cleaning vehicle is a cleaning target section, and the control system is configured to determine whether or not an index representing a degree of contamination in the cleaning target section is greater than or equal to a preset value,
the control system performs cleaning on the cleaning target section in the both-sides communication state if the index is less than the set value, and
the control system performs cleaning on the cleaning target section a plurality of times, comprising at least one of cleaning in the right-side communication state and cleaning in the left-side communication state if the index is greater than or equal to the set value.

8. The cleaning system according to claim 1, further comprising:
a power supply unit that is provided along the transport path and is configured to supply power to the article transport vehicle on the transport path, and
wherein:
the power supply unit comprises a right power supply unit disposed along the right rail and a left power supply unit disposed along the left rail,
the cleaning vehicle comprises:
a second right suction port disposed to oppose the right power supply unit;
a second left suction port disposed to oppose the left power supply unit;
a second right flow path connecting the second right suction port and the negative pressure generation unit; and
a second left flow path connecting the second left suction port and the negative pressure generation unit, and
the communication state changing device is configured to be able to switch between
a single-path communication state in which only one of the right flow path, the left flow path, the second right flow path, and the second left flow path is in communication, and
a multiple-path communication state in which two or more of the flow paths are in communication.
